(19) United States
(12) Patent Application Publication
(10) Pub. No.: US 2016/0005881 A1
(43) Pub. Date: Jan. 7, 2016

(54) STACKED FILMS AND METHOD FOR PRODUCING STACKED FILMS

(71) Applicant: FUJI ELECTRIC CO., LTD., Kawasaki-shi (JP)

(72) Inventors: Takeshi FUJII, Hino-city (JP); Mariko SATO, Fujisawa-city (JP)

(73) Assignee: FUJI ELECTRIC CO., LTD., Kawasaki-shi (JP)

(21) Appl. No.: 14/851,071

(22) Filed: Sep. 11, 2015

Related U.S. Application Data
(63) Continuation of application No. PCT/JP2014/059489, filed on Mar. 31, 2014.

(30) Foreign Application Priority Data
Apr. 18, 2013 (JP) 2013-087575

(51) Int. Cl. H01L 29/786; H01L 21/02; H01L 29/16

(52) U.S. Cl. CPC H01L 29/78687; H01L 29/1606; H01L 29/78603; H01L 21/02527; H01L 21/0242

(57) ABSTRACT

Stacked films includes mica, a self-assembled film and a graphene film. The self-assembled film is formed on the mica. The graphene film is formed over the self-assembled film. The molecules that make up the self-assembled film have hydrophobic main chains.

This application is a continuation under 35 U.S.C. 120 of International Application PCT/JP2014/059489 having the International Filing Date of Mar. 31, 2014, and having the benefit of the earlier filing date of Japanese Application No. 2013-087575, filed Apr. 18, 2013. Each of the identified applications is fully incorporated herein by reference.

### BACKGROUND

1. Technical Field

The present invention relates to stacked films, a method for producing stacked films, and a field-effect transistor.

2. Background Art

Single-layer graphene is currently the object of attention in condensed matter physics. Single-layer graphene refers herein to graphene comprising a single layer of carbon atoms. In graphene, a sheet-like crystal structure is formed through mutual bonding of carbon atoms over sp² bonds. Non-patent literature 1 and Non-patent literature 2 disclose the peculiar quantum conduction of single-layer graphene, such as a half-integer Hall effect, that arises from two-dimensionality.

As is known, single-layer graphene exhibits carrier (electron) mobility of about 15000 cm²/Vs. This value is higher, by one or more orders of magnitude, than the mobility of silicon. Various industrial applications have been proposed that exploit the high mobility of single-layer graphene. Proposed such applications are wide-ranging, and include applications in, for instance, transistors that go beyond silicon, as well as spin injection devices and gas sensors that detect single molecules. Applications in conductive thin films and transparent conductive films have currently garnered attention among the foregoing.

Non-patent literature 3 indicates that high-mobility graphene can be obtained by forming graphene on hexagonal boron nitride (h-BN). Herein, h-BN is an atomically flat insulator. Non-patent literature 3 indicates that graphene formed on h-BN allows realizing high mobility, of 40000 cm²/Vs or higher. The advantages of h-BN over SiO₂ include the following. Firstly, h-BN has an atomically flat surface, and is therefore hardly affected by scattering. By contrast, SiO₂ has an amorphous crystal structure, and, accordingly, is readily influenced by scattering due to surface irregularities. Next, h-BN is hydrophobic, and hence water molecules do not adhere readily thereto. As a result, scattering on account of water molecules adhered to h-BN is unlikely to occur in h-BN. By contrast, water readily adsorbs onto surface hydroxyl groups in SiO₂. Accordingly, scattering due to water molecules adsorbed on SiO₂ is likely to occur in the latter. These reasons underlie the realization of high mobility in graphene that is formed on h-BN. On the other hand, the crystal size of h-BN is very small, of about 1 mm². The crystal size of h-BN is accordingly a challenge that remains to be overcome in the industrial use of graphene formed on h-BN.

Patent literature 1, 2, 3 and 4 disclose field-effect transistors that utilize graphene. In the field-effect transistors of Patent literature 1, 2, 3 and 4, graphene is used in a gate channel. As described above, graphene has high mobility. Accordingly, high-speed operation is expected to be realized in field-effect transistors in which graphene is used in gate channels. Non-patent literature 4 discloses a method for producing a field-effect transistor in which graphene is utilized. Non-patent literature 4 involves transfer of a graphene film formed by chemical vapor deposition (CVD).
Patent literature 1: Japanese Patent Application Publication No. 2011-86937
Patent literature 2: U.S. Pat. No. 8,101,980
Patent literature 3: Japanese Patent Application Publication No. 2013-4972
Patent literature 4: US Patent Application Publication No. 2012/313079.
Non-patent literature 1: K. S. Novoselov, A. K. Geim, S. V. Morozov, D. Jiang, Y. Zhang, S. V. Dubonos, I. V. Grigorieva, A. A. Firsov, Science 306 (2004) 666.
Non-patent literature 2: K. S. Novoselov, D. Jiang, F. Schedin, T. J. Booth, V. V. Khotkevich, S. V. Morozov and K. Geim, Proc. Natl. Acad. Sci. U.S.A. 102 (2005) 10451.
Non-patent literature 3: C. R. Dean, A. F. Young, I. Meric, C. Lee, L. Wang, S. Sorgenfrei, K. Watanabe, T. Taniguchi, P. Kim, K. L. Shepard and J. Hone, Nature Nanotechnology, 5, 722-726 (2010)
Non-patent literature 4:Xuesong Li, et al., “Transfer of Large-Area Graphene Films for High-Performance Transparent Conductive Electrodes”, Nano Lett. 9, (2009) 4359-4362.

The inventors have studied base substrates that are suitable as base substrates for supporting graphene. As a result, the inventors arrived at mica as a conceivably suitable base substrate for supporting graphene. Mica has cleavability. An atomically flat surface can as a result be formed easily in mica. On the other hand, mica exhibits high wettability towards water molecules. Accordingly, the inventors speculated that water molecules on mica might cause a drop in the mobility of graphene that is formed on mica. The inventors assessed therefore instances of non-adsorption of water molecules onto the surface of mica.

### SUMMARY

The present invention provides stacked films. The stacked films comprise mica, a self-assembled film and a graphene film. The self-assembled film is formed on the mica. The graphene film is formed over the self-assembled film. Molecules that make up the self-assembled film have hydrophobic main chains.

The present invention provides stacked films that comprise a graphene film of high mobility.

### BRIEF DESCRIPTION OF THE DRAWINGS

The objects above, as well as other goals, features and advantages will become more apparent in the light of the preferred embodiments described below and accompanying drawings.

FIG. 1 is a cross-sectional structure diagram of stacked films in a first embodiment;

FIGS. 2A and 2B are process cross-sectional structure diagrams illustrating a production method of the stacked films illustrated in FIG. 1;

FIGS. 3A and 3B are process cross-sectional structure diagrams illustrating a production method of the stacked films illustrated in FIG. 1;

FIGS. 4A, 4B and 4C are process cross-sectional structure diagrams illustrating a method for forming a graphene film on a support film;

FIG. 5 is a cross-sectional diagram illustrating a field-effect transistor in a second embodiment;

FIG. 6 is a cross-sectional diagram illustrating a field-effect transistor in a second embodiment;

FIGS. 7A and 7B are process cross-sectional diagrams illustrating a method for producing the field-effect transistor illustrated in FIG. 5;

FIGS. 8A and 8B are process cross-sectional diagrams illustrating a method for producing the field-effect transistor illustrated in FIG. 5;

FIGS. 9A and 9B are process cross-sectional diagrams illustrating a method for producing the field-effect transistor illustrated in FIG. 5; and

FIGS. 10A and 10B are process cross-sectional diagrams illustrating a method for producing the field-effect transistor illustrated in FIG. 6.

### DETAILED DESCRIPTION

Embodiments of the present invention will be explained next with reference to accompanying drawings. In all the drawings, identical constituent elements will be denoted with identical reference symbols, and an explanation thereof may be omitted, as appropriate. The drawings are schematic diagrams, and thus may not necessarily match actual dimensional ratios.

### First Embodiment

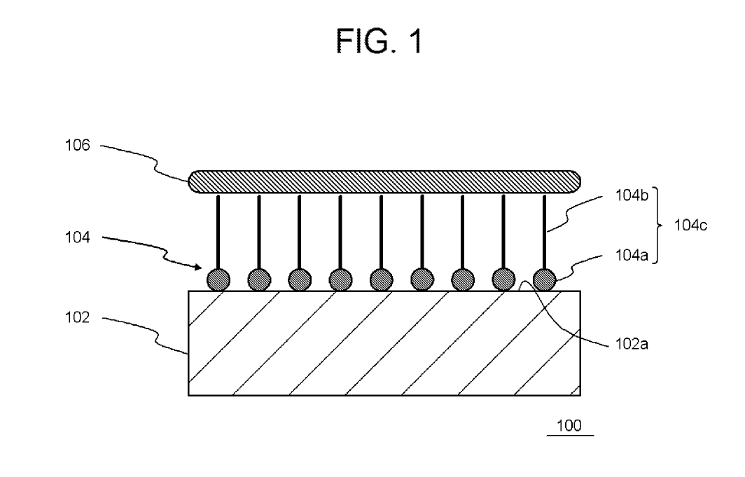

FIG. 1 is a cross-sectional structure diagram of stacked films 100 in a first embodiment. As illustrated in FIG. 1, the stacked films 100 comprise mica 102, a self-assembled film 104 and a graphene film 106. The self-assembled film 104 is formed on the mica 102. The graphene film 106 is formed over the self-assembled film 104. Molecules 104c that make up the self-assembled film 104 have a hydrophobic main chain 104b.

Synthetic mica may be used as the mica 102. Examples of synthetic mica include, for instance, fluorophlogopite mica (KMg₃AlSi₃O₁₀F₂). The mica 102 has cleavability. Accordingly, an atomically flat surface can be formed easily on the mica 102. A surface 102a of the mica 102 in the stacked films 100 illustrated in FIG. 1 is formed to be atomically flat. The surface 102a is a surface that opposes the graphene film 106 across the self-assembled film 104. The thickness of the mica 102 is not particularly limited, but may be set to be 100 nm or greater. When the mica 102 has a thickness of 100 nm or greater, the mica 102 is easier to handle than in an instance where the mica 102 is excessively thin.

The self-assembled film 104 is made up of the molecules 104c. The molecules 104c comprise a functional group 104a and a main chain 104b. The functional group 104a reacts chemically with the surface 102a of the mica 102. As a result of this chemical reaction, the functional group 104a is brought into close contact with the surface 102a of the mica 102. The functional group 104a may be a reactive group that elicits silane coupling with the mica 102. The main chain 104b is hydrophobic. Adsorption of water molecules onto the surface 102a of the mica 102 is prevented thereby. This precludes as a result drops in the mobility of the graphene film 106, caused by water molecules on the surface 102a of the mica 102. The main chain 104b may have an inactive end on the side at which the graphene film 106 is formed. The self-assembled film 104 may be a self-assembled monolayer (SAM). In this case, the self-assembled film 104 constitutes a monolayer. In a case where the self-assembled film 104 forms a monolayer, not only the surface 102a of the mica 102 but also the surface of the self-assembled film 104 is formed atomically flat. Graphene that is formed on such an atomically flat surface has high mobility. In the present embodiment, the self-assembled film 104 is not particularly limited, so long as the latter has the above characteristics, and may comprise at least one selected from the group consisting of hexamethyldisilazane (HMDS), octyltrichlorosilane (OTS), octadecyltrichlorosilane (ODTS) and perfluoroocthyltrichlorosilane (PFOTS).

The graphene film 106 is formed of graphene. The number of layers of the graphene film 106 may be set to range, for instance, from 1 to 10. The number of layers of the graphene film 106 can be modified, as appropriate, depending on the application method of the stacked films 100. For instance, the number of layers of the graphene film 106 may be set to 1, in a case where high mobility is required from the graphene film 106. High mobility can be realized in such single-layer graphene. The number of layers of the graphene film 106 may be set to about 2 to 3 in a case where stacked films 100 are used in a transistor. That is because gap generation by two-layer graphene or three-layer graphene is important in transistors. On the other hand, an upper limit of the number of layers of the graphene film 106 is preferably set to about 10, in a case where the stacked films 100 are used in a transparent conductive film. This derives from the optical absorption of graphene. Graphene exhibits high optical absorption, of about 2.3%, per atomic layer. Accordingly, light cannot reach effectively the lower side of the graphene film 106 when the number of layers of the graphene film 106 exceeds 10 by a significant margin. In a case where the number of layers of the graphene film 106 is about 10, then the optical transmittance of the graphene film 106 in the thickness direction is preferably 70% or higher.

Preferably, van der Waals bonds, and not strong bonds such as ionic bonds or covalent bonds, are formed at the interface between the graphene film 106 and the self-assembled film 104. Formation of ionic bonds or covalent bonds at the interface between the graphene film 106 and the self-assembled film 104 is prevented in a case where the main chain 104b has an inactive end on the side at which the graphene film 106 is formed.

In the stacked films 100 of the present embodiment, the main chain 104b of the molecules 104c that make up the self-assembled film 104 is hydrophobic. Accordingly, it becomes possible to prevent adsorption of water molecules onto the surface 102a of the mica 102. This precludes as a result drops in the mobility of the graphene film 106 caused by water molecules. Stacked films 100 that comprise a graphene film 106 having high mobility is provided as a result in the present embodiment.

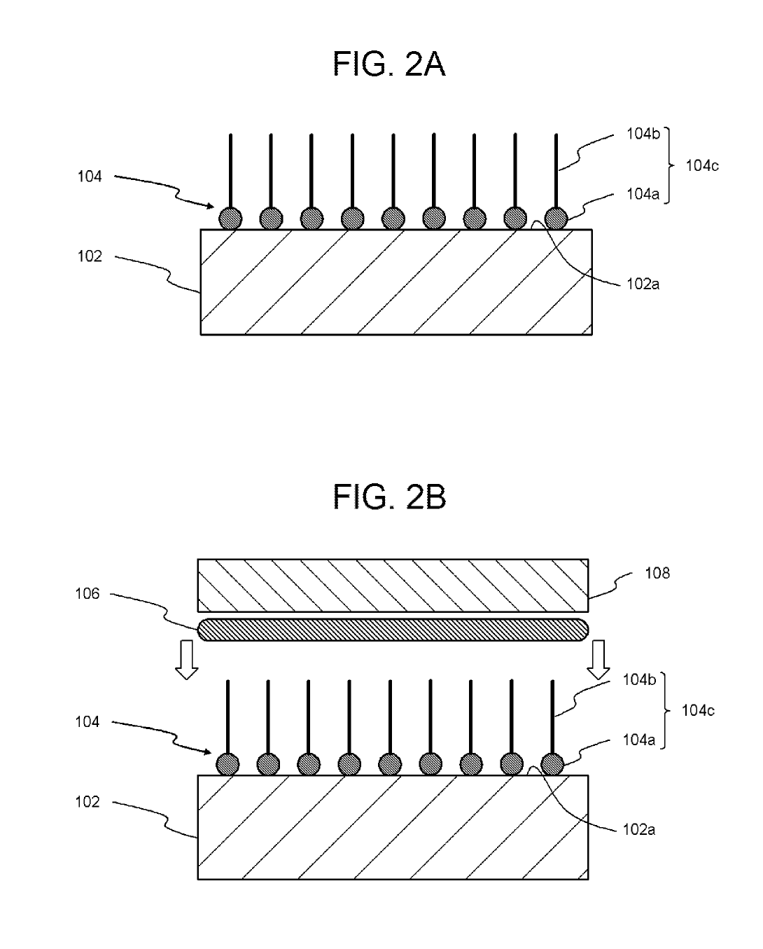

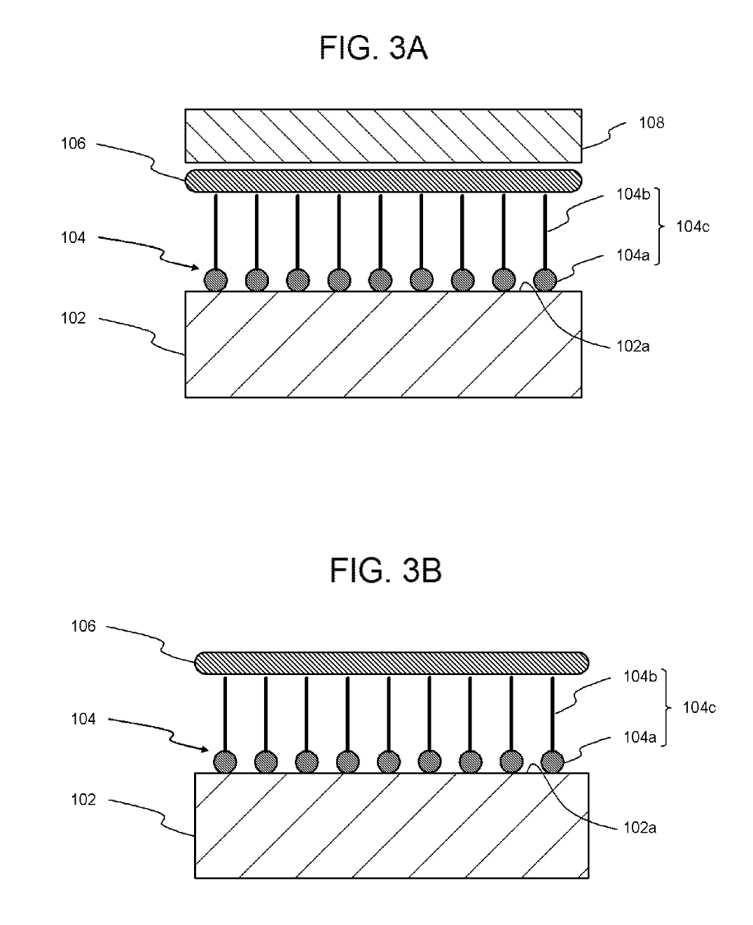

A method for producing the stacked films 100 of the present embodiment will be explained next with reference to FIGS. 2A and 2B and FIGS. 3A and 3B. FIGS. 2A and 2B and FIGS. 3A and 3B are process cross-sectional structure diagrams illustrating a production method of the stacked films 100 illustrated in FIG. 1.

Firstly, the mica 102 is formed through cleaving of a mica substrate (not shown). The mica substrate is cleaved in an atmosphere (for instance, nitrogen atmosphere) having few oxygen molecules and water molecules. Specifically, cleaving of the mica substrate may be performed in a glove box. The mica 102 obtained by cleaving has the atomically flat surface 102a.

Next, the self-assembled film 104 is formed on the mica 102 (FIG. 2A). Various methods (for instance, coating, dipping, spin coating or atmosphere exposure) can be resorted to herein to form the self-assembled film 104. The self-assembled film 104 is formed through self-organizing aggregation of the plurality of molecules 104c on the surface 102a of the mica 102. The functional group 104a of the molecules 104c reacts herein with the surface 102a of the mica 102, to bring about close contact with the surface 102a of the mica 102. The functional group 104a in this case may be silane-coupled to the surface 102a of the mica 102. The main chain 104b is hydrophobic. The main chain 104b may have an inactive end on the side at which the graphene film 106 is formed. In the present embodiment, the self-assembled film 104 may comprise at least one selected from the group consisting of hexamethyldisilazane (HMDS), octyltrichlorosilane (OTS), octadecyltrichlorosilane (ODTS) and perfluoroocthyltrichlorosilane (PFOTS).

A formation method of the self-assembled film 104 wherein the latter is hexamethyldisilazane (HMDS) will be explained herein. An HMDS liquid in which HMDS is in a liquid-phase state is prepared first. The mica 102 is next impregnated with the HMDS liquid. The mica 102 is impregnated with the HMDS liquid over about 10 hours. The self-assembled film 104 is formed as a result, through self-organizing aggregation of the HMDS molecules on the surface 102a of the mica 102. After immersion, the mica 102 is retrieved from the HMDS liquid. The mica 102 is dried thereafter by nitrogen blowing. As another method, the mica 102 may be exposed to an HMDS gas atmosphere. The self-assembled film 104 becomes formed on the surface 102a of the mica 102 in accordance with this method as well.

The graphene film 106 is formed next over the self-assembled film 104 (FIG. 2B, FIGS. 3A, 3B). The graphene film 106 may be formed over the self-assembled film 104 in the below-described manner. Firstly, the graphene film 106 is formed on a support film 108. The graphene film 106 is held as a result on the support film 108. Next, the graphene film 106 held on the support film 108 is pressed against the self-assembled film 104 (FIG. 2B, FIG. 3A). Thereafter, the support film 108 is removed from the graphene film 106 (FIG. 3B).

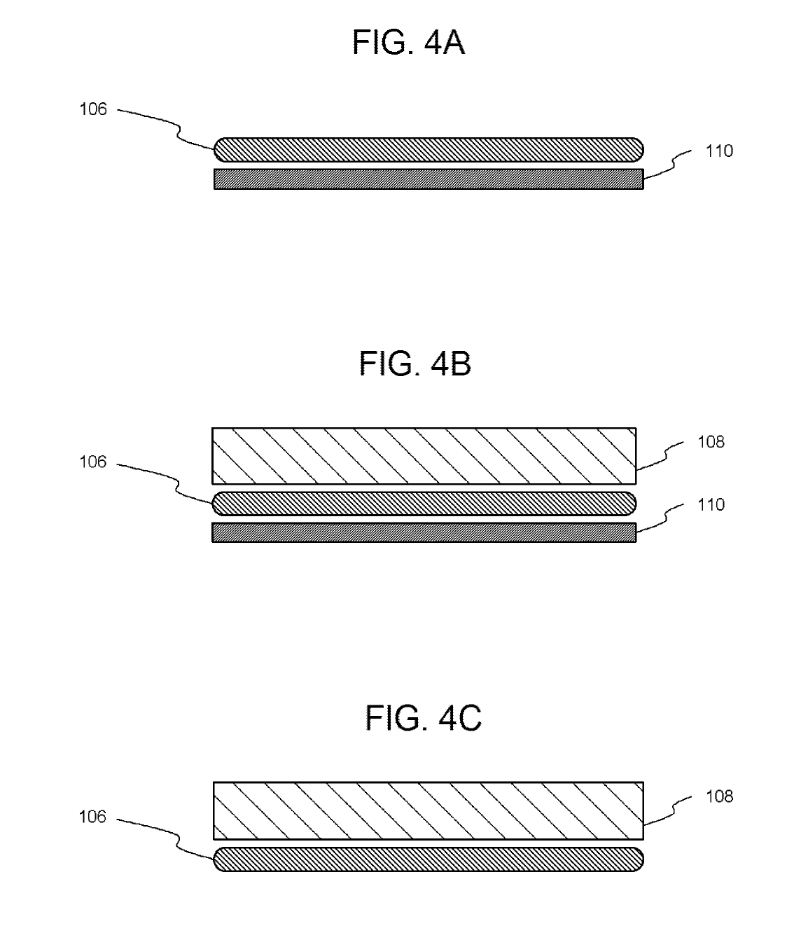

The method for forming the graphene film 106 on the support film 108 will be explained in detail with reference to FIGS. 4A, 4B and 4C. FIGS. 4A, 4B and 4C are process cross-sectional structure diagrams illustrating a method for forming the graphene film 106 on the support film 108.

Firstly, the graphene film 106 is formed on a metal film 110. The metal film 110 is formed of a transition metal. Examples of the transition metal of the metal film 110 include Fe, Co, Ni, Cu, Mo, Ru, Rh, Pd, W, Re, Ir, Pt and alloys of the foregoing. The metal film 110 may be formed on a single crystal or polycrystal. The metal film 110 may be formed as a foil, a thin film or in bulk. In the present embodiment a copper foil is formed as the metal film 110. The metal film 110 functions as a support substrate of the graphene film 106, and may also function as a catalyst in the formation of the graphene film 106, as described below.

The graphene film 106 on the metal film 110 is formed by CVD or physical vapor deposition (PVD). An instance where the graphene film 106 is formed by CVD will be explained first. In CVD, the metal film 110 kept under various conditions that include ultra-high vacuum not higher than 1×10⁻⁷ Pa, low pressure ranging from about 10 to 10000 Pa, atmospheric pressure and the like, is heated at about 600 to 1200° C. A hydrocarbon gas (for instance, methane) that comprises carbon atoms is blown onto the metal film 110 in this state. The hydrocarbon gas undergoes dissociative adsorption as a result of this process. The carbon atoms derived from the gas that is supplied are acted upon by the catalytic effect of the surface of the metal film 110, and nucleation of graphene starts. The graphene film 106 becomes formed on the metal film 110 as graphene grows this way (FIG. 4A). In the above CVD process, the surface of the metal film 110 on which the graphene film 106 is formed may be a single-crystal surface.

An instance where the graphene film 106 is formed by PVD will be explained next. Graphene may be grown, in accordance with PVD, for instance by molecular beam epitaxy (MBE) or pulsed laser deposition (PLD). In MBE, carbon atoms are generated through heating of graphite, at a temperature in the range 1200 to 2000° C., in ultra-high vacuum. The carbon atoms in the form of a molecular beam are supplied to the surface of the heated metal film 110. The metal film 110 functions in this case as a catalyst. The graphene film 106 becomes formed on the metal film 110 by virtue of the catalytic effect of the latter (FIG. 4A). In PLD, by contrast, graphite is ablated by a KrF excimer laser in ultra-high vacuum. Carbon that is thus evaporated instantly forms a molecular beam. The carbon molecular beam is supplied onto the surface of the heated metal film 110. The graphene film 106 becomes formed as a result on the surface of the metal film 110 (FIG. 4A).

After formation of the graphene film 106 on the metal film 110, as described above, the support film 108 is formed on the graphene film 106, so as to come into contact with the surface of the graphene film 106 (FIG. 4B). Thereafter, the metal film 110 is removed by etching (FIG. 4C). The support film 108 must be formed of a material that is capable of holding the graphene film 106. The support film 108 must also be resistant to an etchant that is used for etching of the metal film 110. Given the above requirements, the support film 108 may be formed of a material that is in liquid state at the point in time of coming into contact with the graphene film 106 and that can solidify thereafter. Specifically, the support film 108 may be formed by a solvent-soluble resin in a state of being dissolved in a solvent. In this case, the support film 108 is formed through volatilization of the solvent. As another example, the support film 108 may be formed of a precursor (for instance, a prepolymer) prior to becoming a polymer. In this case, the support film 108 is formed through polymerization of the precursor. Other preferable properties that are required from the support film 108 include, for instance, not affecting negatively the graphene film 106 when the support film 108 is removed from the graphene film 106. More specifically, polymethyl methacrylate (PMMA) or polydimethylsiloxane (PDMS) is suitably used as the support film 108. For instance, wet etching using an acid, or dry etching such as reactive ion etching, may be resorted to herein to etch the metal film 110.

The graphene film 106 thus held on the support film 108 is pressed against the self-assembled film 106 on the mica 102, as illustrated in FIG. 2B. In this case, the graphene film 106 is pressed against the self-assembled film 106 by a pressure of about 0.5 kg/cm², at a temperature of about 80° C. As a result, the self-assembled film 104 and the graphene film 106 come into close contact with each other, as illustrated in FIG. 3A.

The support film 108 is removed next from the graphene film 106 (FIG. 3B). In this case, the support film 108 may be impregnated with a solution that dissolves the support film 108. The support film 108 is removed as a result. To remove the support film 108, a method is preferred that does not affect the self-assembled film 104 or the graphene film 106.

The stacked films 100 are formed as described above. In the stacked films 100 formed as described above, the main chain 104b of the molecules 104c that make up the self-assembled film 104 is hydrophobic. Accordingly, it becomes possible to prevent adsorption of water molecules onto the surface 102a of the mica 102. As a result, this prevents drops in the mobility of the graphene film 106 caused by water molecules. The stacked films 100 that comprise the graphene film 106 having high mobility is provided as a result in the present embodiment.

### Second Embodiment

In a second embodiment, the stacked films 100 of the first embodiment are used as a field-effect transistor. In the present embodiment, specifically, field-effect transistors 200a and 200b are provided in which the graphene film 106 comprised in the stacked films 100 functions as a channel.

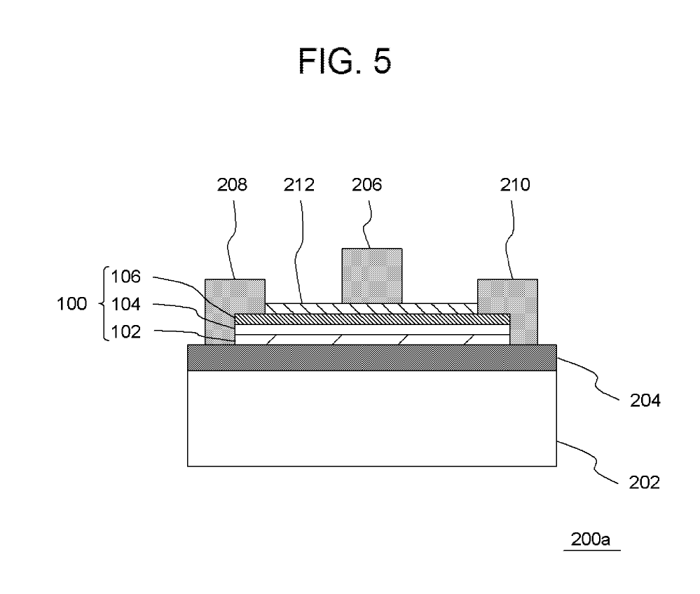

The field-effect transistor 200a will be explained next with reference to FIG. 5. The field-effect transistor 200a is a top gate-type transistor. The field-effect transistor 200a comprises the stacked films 100, a drain electrode 208, a source electrode 210, a gate insulating film 212 and a gate electrode 206. The drain electrode 208 and the source electrode 210 are connected to the graphene film 106. The gate insulating film 212 opposes the mica 102 across the graphene film 106 and the self-assembled film 104. The gate electrode 206 opposes the graphene film 106 across the gate insulating film 212. More specifically, the field-effect transistor 200a further comprises a substrate 202. The stacked films 100 are formed on the substrate 202 in such a manner that the mica 102 opposes the substrate 202. The gate insulating film 212 and the gate electrode 206 are formed on the graphene film 106. The drain electrode 208 and the source electrode 210 are formed on the substrate 202. An oxide film 204 is formed on the surface of the substrate 202, as illustrated in FIG. 5. In this case, the stacked films 100 are formed on the oxide film 204.

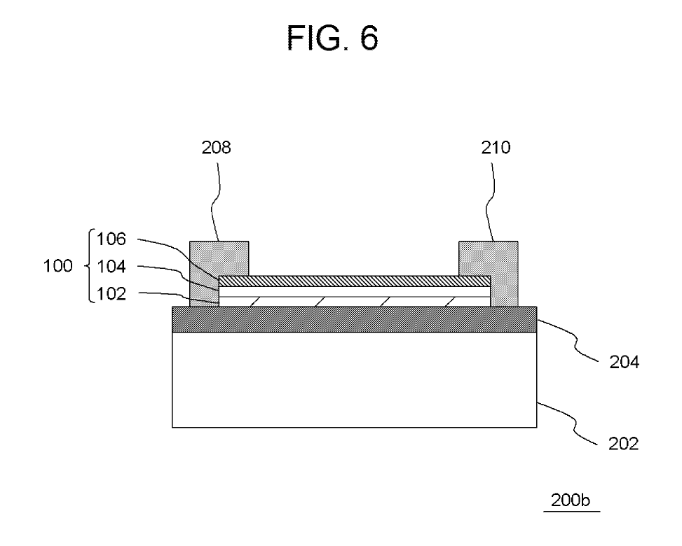

The field-effect transistor 200b will be explained next with reference to FIG. 6. The field-effect transistor 200b is a bottom gate-type transistor. The field-effect transistor 200b comprises the stacked films 100, the drain electrode 208, the source electrode 210, an insulating film (oxide film 204) and a gate electrode (substrate 202). The drain electrode 208 and the source electrode 210 are connected to the graphene film 106. The insulating film (oxide film 204) opposes the graphene film 106 across the mica 102 and the self-assembled film 104. The gate electrode (substrate 202) opposes the mica 102 across the insulating film (oxide film 204). More specifically, the field-effect transistor 200b further comprises the substrate 202. The oxide film 204 is formed on the surface of the substrate 202. The stacked films 100 are formed on the substrate 202 in such a manner that the mica 102 opposes the oxide film 204. The oxide film 204 constitutes an insulating film. The substrate 202 constitutes a gate electrode. The drain electrode 208 and the source electrode 210 are formed on the oxide film 204.

In the field-effect transistors 200a and 200b of the present embodiment the graphene film 106 comprised in the stacked films 100 functions as a channel. The graphene film 106 in the stacked films 100 can realize high mobility, as described above. As a result, the field-effect transistors 200a and 200b of the present embodiment allow realizing high-speed operation.

The field-effect transistor 200a will be explained next in detail. The field-effect transistor 200a is a top gate-type transistor. The field-effect transistor 200a comprises the substrate 202, the stacked films 100, the gate insulating film 212, the gate electrode 206, the drain electrode 208 and the source electrode 210. The substrate 202 may be a semiconductor substrate (for instance, a silicon substrate). The oxide film 204 is formed on the surface of the substrate 202. The oxide film 204 may be formed of an insulating film (for instance, of silicon dioxide, aluminum oxide, hafnium oxide or tantalum oxide). The stacked films 100 are formed on the substrate 202 in such a manner that the mica 102 is in contact with the oxide film 204. The gate insulating film 212 is formed on the stacked films 100 in such a way so as to be in contact with the graphene film 106. The gate insulating film 212 is formed by an insulating film (for instance, of silicon dioxide, aluminum oxide, hafnium oxide or tantalum oxide). The gate electrode 206 is formed on the gate insulating film 212. The gate electrode 206 is electrically insulated, by the gate insulating film 212, from the drain electrode 208 and the source electrode 210. The gate electrode 206 is formed of a metal (for instance, aluminum, gold, platinum, titanium, chromium or a multilayer film of the foregoing). The drain electrode 208 and the source electrode 210 are formed so as to flank the gate electrode 206 in a plan view. The drain electrode 208 and the source electrode 210 are connected to the graphene film 106. The drain electrode 208 and the source electrode 210 are formed so as to cover the ends of the stacked films 100 and part of the oxide film 204, as illustrated in FIG. 5. The drain electrode 208 and the source electrode 210 are formed of a metal (for instance, aluminum, gold, platinum, nickel, titanium, chromium or a multilayer film of the foregoing). The drain electrode 208 and the source electrode 210 may be formed of the same metal as that of the gate electrode 206. The graphene film 106 in the field-effect transistor 200a functions as a channel.

The field-effect transistor 200b will be explained next in detail. The field-effect transistor 200b is a bottom gate-type transistor. The field-effect transistor 200b comprises the substrate 202, the oxide film 204, the stacked films 100, the drain electrode 208 and the source electrode 210. The substrate 202 in the field-effect transistor 200b functions as a gate electrode. Accordingly, the substrate 202 must be formed of a conductive member. Specifically, the substrate 202 is formed of, for instance, silicon doped with an impurity at a high concentration, or a metal (for instance, aluminum, gold, tantalum nitride or titanium nitride). As another example, the substrate 202 may be a transparent substrate formed by ITO (indium tin oxide). The oxide film 204 is formed on the surface of the substrate 202. In the field-effect transistor 200b, the oxide film 204 functions as a gate insulating film, together with the mica 102. In the transistor 200b, accordingly, the thickness of the mica 102 and the thickness of the oxide film 204 are selected, as appropriate, so as to obtain desired characteristics. The oxide film 204 is formed, for instance, by an insulating film (for instance, silicon dioxide, aluminum oxide, hafnium oxide or tantalum oxide). The stacked films 100 are formed on the substrate 202 in such a manner that the mica 102 is in contact with the oxide film 204. The drain electrode 208 and the source electrode 210 are connected to the graphene film 106. The drain electrode 208 and the source electrode 210 are formed so as to cover the ends of the stacked films 100 and part of the oxide film 204, as illustrated in FIG. 6. The drain electrode 208 and the source electrode 210 are formed of a metal (for instance, aluminum, gold, platinum, titanium, chromium or a multilayer film of the foregoing). The graphene film 106 in the field-effect transistor 200b functions as a channel.

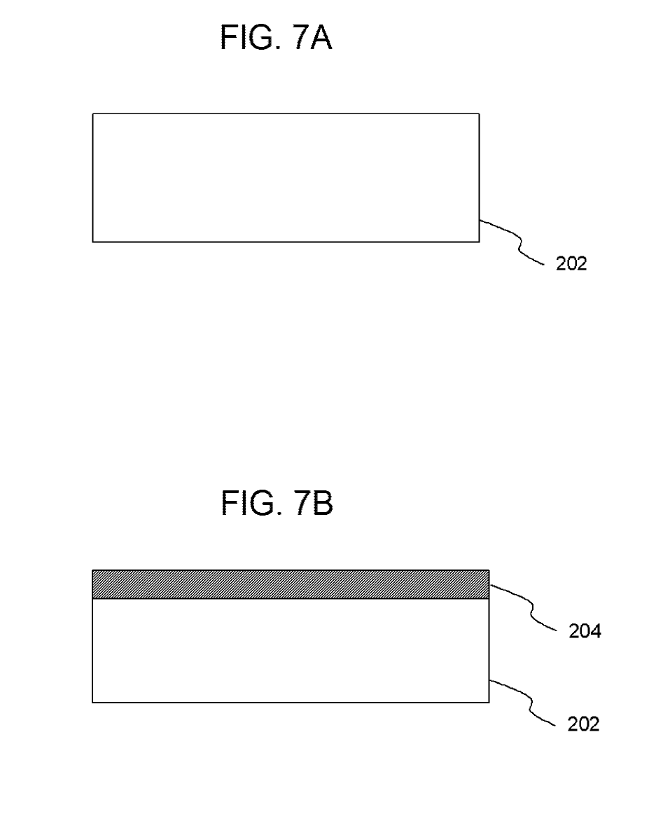

The method for producing the field-effect transistor 200a will be explained next in detail with reference to FIGS. 7A, 7B, 8A, 8B, 9A and 9B. FIGS. 7A, 7B, 8A, 8B, 9A and 9B are process cross-sectional diagrams illustrating a production method of the field-effect transistor 200a illustrated in FIG. 5.

The substrate 202 is prepared first (FIG. 7A). The substrate 202 may be a semiconductor substrate (for instance, a silicon substrate) or a metal substrate (for instance, of aluminum, gold, tantalum nitride or titanium nitride). As another example, the substrate 202 may be a transparent substrate formed of ITO (indium tin oxide).

The oxide film 204 is formed next on the surface of the substrate 202 (FIG. 7B). The oxide film 204 may be formed through thermal oxidation.

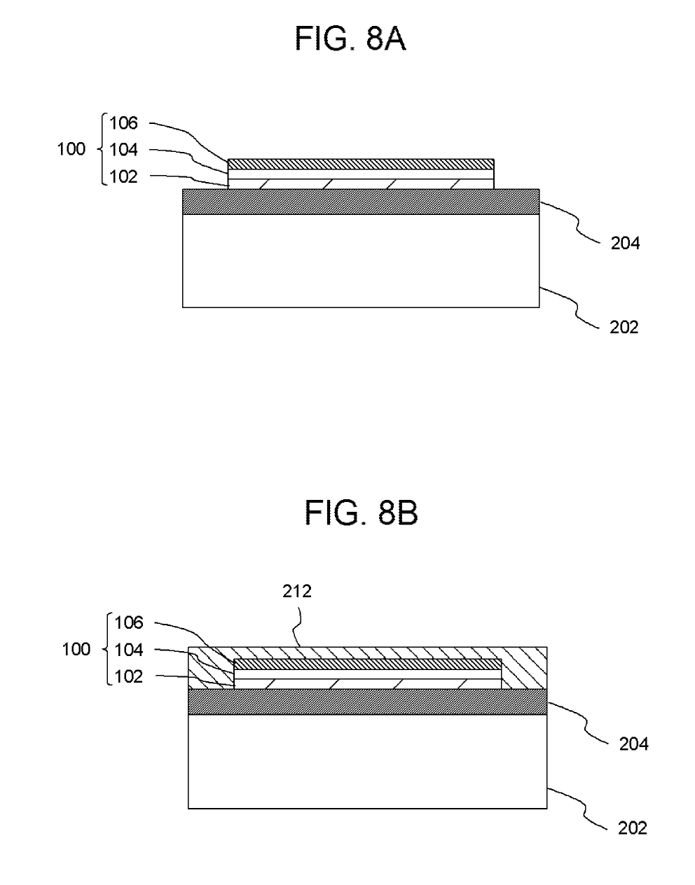

Next, the stacked films 100 are set on the oxide film 204 (FIG. 8A). The stacked films 100 are a stack produced according to the production method of the first embodiment. The stacked films 100 are formed on the substrate 202 in such a manner that the mica 102 is in contact with the oxide film 204.

Next, the gate insulating film 212 is formed on the substrate 202 in such a way so as to cover the stacked films 100 (FIG. 8B). The gate insulating film 212 may be formed of, for instance, silicon dioxide, aluminum oxide or hafnium oxide. Herein, CVD or atomic layer deposition (ALD) may be resorted to in order to form the gate insulating film 212.

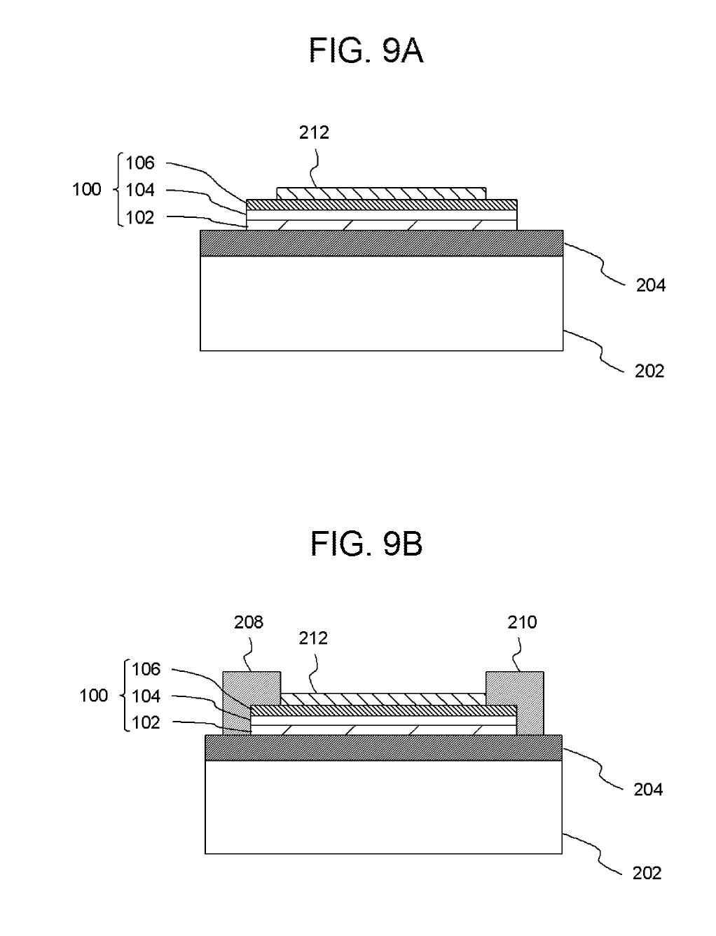

The gate insulating film 212 is etched next by photolithography, as illustrated in FIG. 9A. In FIG. 9A, the gate insulating film 212 is etched in such a manner that the ends of the stacked films 100 are exposed.

Next, the drain electrode 208 and the source electrode 210 are formed on the substrate 202. The drain electrode 208 and the source electrode 210 are formed on the ends of the stacked films 100, as illustrated in FIG. 9B. The drain electrode 208 and the source electrode 210 become connected as a result to the graphene film 106. The drain electrode 208 and the source electrode 210 are formed of a metal. Sputtering or vapor deposition may be resorted to herein to form the drain electrode 208 and the source electrode 210.

Next, the gate electrode 206 is formed on the gate insulating film 212. As a result there is obtained the field-effect transistor 200a illustrated in FIG. 5. The gate electrode 206 is formed of a metal. Self alignment may be resorted to in order to form the gate electrode 206. In self alignment, the metal that forms the gate electrode 206 is formed on the gate insulating film 212 on a self-aligned manner. The gate electrode 206 is formed by photolithography.

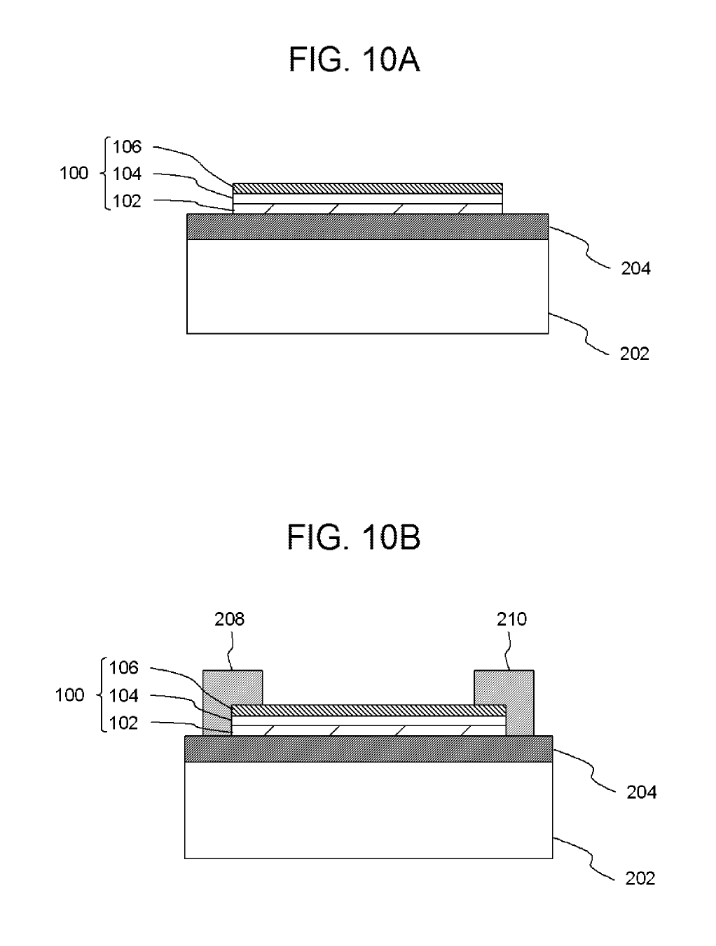

The method for producing the field-effect transistor 200b will be explained next in detail with reference to FIGS. 7A and 7B and FIGS. 10A and 10B. FIGS. 10A and 10B are process cross-sectional diagrams illustrating a method for producing the field-effect transistor 200b illustrated in FIG. 6.

Firstly, the substrate 202 is prepared in the same way as in the case of the field-effect transistor 200a (FIG. 7A). The substrate 202 in the field-effect transistor 200b functions as a gate electrode. Accordingly, the substrate 202 must be formed of a conductive member. Specifically, the substrate 202 is formed of, for instance, silicon doped with an impurity at a high concentration, or of a metal (for instance, aluminum, gold, tantalum nitride or titanium nitride).

The oxide film 204 is formed next on the surface of the substrate 202, in the same way as in the case of the field-effect transistor 200a (FIG. 7B). In the field-effect transistor 200b, the oxide film 204 functions as a gate insulating film. Accordingly, the thickness and material of the oxide film 204 are selected in accordance with desired characteristics. The oxide film 204 may be formed of silicon dioxide, aluminum oxide or hafnium oxide. The oxide film 204 may be formed through thermal oxidation of the substrate 202. Alternatively, the oxide film 204 may be deposited on the substrate 202 by CVD or ALD.

Next, the stacked films 100 are set on the oxide film 204 (FIG. 10A). The stacked films 100 are a stack produced according to the production method of the first embodiment. The stacked films 100 are formed on the substrate 202 in such a manner that the mica 102 is in contact with the oxide film 204. Next, a pattern is formed, by photolithography, on the graphene film 106. Unwanted portions of the graphene film 106 are removed, by oxygen plasma asking, using that pattern. The graphene film 106 exhibits as a result a desired channel width and distance.

Next, the drain electrode 208 and the source electrode 210 are formed on the substrate 202. The drain electrode 208 and the source electrode 210 are formed on the ends of the stacked films 100, as illustrated in FIG. 10B. The drain electrode 208 and the source electrode 210 become connected as a result to the graphene film 106. The drain electrode 208 and the source electrode 210 are formed of a metal. Sputtering or vapor deposition may be resorted to herein to form the drain electrode 208 and the source electrode 210. The field-effect transistor 200b illustrated in FIG. 6 is obtained as a result.

In the field-effect transistors 200a and 200b formed as described above, the graphene film 106 comprised in the stacked films 100 functions as a channel. High mobility can be realized, as described above, in the graphene film 106 in the stacked films 100. As a result, the field-effect transistors 200a and 200b of the present embodiment allow realizing high-speed operation.

### Examples

Examples of the stacked films 100 of the first embodiment will be explained next. The examples are samples of the stacked films 100 produced in accordance with the embodiments described above. The materials, usage amounts, proportions, process features, process procedures, as well as the specific orientation, arrangement and the like of elements and members can be modified, as appropriate, would departing from the scope of the present invention. The scope of the present invention is therefore not limited to the specific examples below. The explanation below will refer to figures already explained.

Herein, a 10 mm² square copper foil (100 μm thick) was used as the metal film 110. The arithmetic mean roughness Ra of the copper foil is 1 nm. The copper foil was placed in a CVD reactor, and the pressure in the reactor was reduced down to 1×10⁻³ Pa. The temperature inside the reactor was raised to 1000° C., at a temperature raise rate of 50° C./min, in a state where hydrogen at 5 Pa (3.8×10⁻² Torr) was introduced into the reactor. Thereafter, the supply of hydrogen was discontinued, in a state where the temperature inside the reactor was held at 1000° C., and methane, as a starting gas, was introduced at about 4.0×10² Pa (about 3 Torr). Film formation was performed over 10 minutes in a state where the substrate temperature of the copper foil and the gas pressure were maintained. Film formation was followed by quenching at a cooling rate of 100° C./sec, to grow the graphene film 106 on the copper foil.

Next, 20 μl of a PMMA solution, dissolved to 10 wt % in dichlorobenzene, was dripped onto the surface of the graphene film 106, and the PMMA solution was spin-coated under conditions that involved a rotational speed of 4000 rpm, for 60 seconds. Thereafter, the PMMA solution was dried under conditions of 40° C., for 30 minutes, to form the support film 108 by a PMMA film.

Next, the sample having the support film 108 formed thereon was immersed in a mixed solution of 10 ml of hydrochloric acid, 10 ml of hydrogen peroxide and 50 ml of pure water, to remove completely the copper foil by etching. Thereafter, the sample was washed for 5 minutes with running water, and was dried, to form a stack comprising the graphene film 106 and the support film 108.

Herein, 10 mm² fluorophlogopite mica (synthetic mica) (thickness 0.5 mm) was used as the mica 102. Firstly, an adhesive tape was affixed to, and then stripped off, the surface of synthetic mica, inside a glove box with controlled water and oxygen. A fresh cleavage plane was formed as a result on the surface of the synthetic mica. The arithmetic mean roughness Ra of the cleavage surface was 0.1 nm or less. Next, the mica 102 was immersed in hexamethyldisilazane (HMDS) liquid, and was left to stand for 10 hours. Thereafter, the mica 102 was dried by nitrogen blowing, to form a monolayer self-assembled film 104 comprising HMDS. The stack comprising the graphene film 106 and the support film 108 was pressed in an orientation such that the graphene film 106 opposed the surface of the self-assembled film 104. Pressure-bonding conditions herein were 80° C. and 0.5 kg/cm². The sample was heated next at 180° C. for 30 minutes. As a result PMMA was softened. The graphene film 106 was thus brought into close contact with the surface of HMDS being the self-assembled film 104.

Lastly, the sample was immersed for 5 minutes in acetone. The PMMA of the support film 108 was removed as a result from the surface of the graphene film 106. The sample was further cleaned for 5 minutes in ultra-pure water. The sample obtained as a result of the above process yielded Example 1.

Example 2 will be explained next. Example 2 is identical to Example 1, but herein octyltrichlorosilane (OTS), and not HMDS, was used as the self-assembled film 104.

Example 3 will be explained next. Example 3 was identical to Example 1, but herein octadecyltrichlorosilane (ODTS), and not HMDS, was used as the self-assembled film 104.

Example 4 will be explained next. Example 4 was identical to Example 1, but herein perfluoroocthyltrichlorosilane (PFOTS), and not HMDS, was used as the self-assembled film 104.

Comparative Example 1 will be explained next. Comparative Example 1 is identical to Example 1, but herein no self-assembled film 104 is formed.

Experiments were performed to work out the contact angle and mobility in the samples of Examples 1 to 4 and Comparative Example 1. Table 1 illustrates experimental results pertaining to the samples of Examples 1 to 4 and Comparative Example 1. Example 1, where HMDS is formed as the self-assembled film 104, exhibits mobility about 10-fold that of Comparative Example 1, in which no self-assembled film 104 is formed. Examples 2 to 4 as well exhibit higher mobility than that of Comparative Example 1. The contact angle increased in the order Comparative Example 1, Examples 1, 2, 3 and 4. Mobility increases also in this order. Specifically, Table 1 illustrates a trend whereby mobility increases proportionally to the contact angle. A comparison between the contact angle in Comparative Example 1 and the contact angles in Examples 1 to 4 suggests that the vicinity of the surface 102a of the mica 102 is rendered hydrophobic on account of the presence of the self-assembled film 104. The proportionality relationship between mobility and contact angle suggests that mobility is enhanced when water molecules are prevented from being mixed in the vicinity of the surface 102a of the mica 102. The effect of the present invention was thus demonstrated.

TABLE 1

| | Self-assembled | Contact angle | Mobility |
|---|---|---|---|
| | film | (°) | (cm²/Vs) |
| Example 1 | HMDS | 87 | 35600 |
| Example 2 | OTS | 102 | 40300 |
| Example 3 | ODTS | 109 | 51200 |
| Example 4 | PFOTS | 114 | 57800 |
| Comparative | None | 25 | 3020 |
| Example 1 | | | |

Embodiments of the present invention have been explained above in specific terms. The above-described embodiments and examples has been described in order to explain the invention, but the scope of the invention of the present application is meant to be defined on the basis of the disclosure of the appended claims. The claims encompass also variations that lie within the scope of the present invention, including other combinations of the embodiments.

The present application claims priority from Japanese Patent Application No. 2013-087575 filed on Apr. 18, 2013, the entire contents of which are hereby incorporated by reference.

What is claimed is:

1. Stacked films, comprising:
mica;
a self-assembled film formed on the mica; and
a graphene film formed over the self-assembled film, wherein
a surface of the self-assembled film is hydrophobic.

2. The stacked films according to claim 1, wherein a surface of the mica is formed to be atomically flat.

3. The stacked films according to claim 1, wherein the self-assembled film comprises at least one selected from the group consisting of hexamethyldisilazane, octyltrichlorosilane, octadecyltrichlorosilane and perfluoroocthyltrichlorosilane.

4. The stacked films according to claim 1, wherein the self-assembled film is a monolayer.

5. The stacked films according to claim 1, wherein a number of layers of the graphene films ranges from 1 to 10.

6. The stacked films according to claim 1, wherein a thickness of the mica is 100 nm or greater.

7. A field-effect transistor, comprising:
the stacked films according to claim 1;
a drain electrode and a source electrode connected to the graphene film;
a gate insulating film formed on a surface of the graphene film; and
a gate electrode on the gate insulating film opposing the graphene film.

8. The field-effect transistor according to claim 7, further comprising:
a substrate, wherein
an oxide film is formed on a surface of the substrate;
the stacked films are formed so that the mica is on the oxide film;
the gate insulating film is formed on the graphene film of the stacked films; and
the drain electrode and the source electrode are formed on the oxide film and are connected to the graphene film.

9. A field-effect transistor, comprising:
the stacked films according to claim 1;
an insulating film formed on a gate electrode,
wherein the stacked films are formed so that the mica is on the insulating film; and
a drain electrode and a source electrode connected to the graphene film of the stacked films.

10. The field-effect transistor according to claim 9, further comprising:
a substrate, wherein
an oxide film is formed on a surface of the substrate;
the stacked films are formed so that the mica is on the oxide film;
the oxide film is the insulating film;
the substrate is the gate electrode; and
the drain electrode and the source electrode are formed on the oxide film and are connected to the graphene film of the stacked films.

11. A method for producing stacked films,
the method comprising:
a step of forming a self-assembled film on mica; and
a step of forming a graphene film over the self-assembled film, wherein
the surface of the self-assembled film is hydrophobic.

12. The method for producing stacked films according to claim 11, wherein the step of forming the self-assembled film on the mica comprises:
a step of immersing the mica in a liquid that contains molecules that make up the self-assembled film; and
a step of drying the mica, after the step of immersing the mica in the liquid.

13. The method for producing stacked films according to claim 11, wherein the step of forming the graphene film over the self-assembled film comprises:
a step of forming a support film on the graphene film, and holding the graphene film on the support film,
a step of pressing the graphene film, which is held on the support film, against the self-assembled film, and
a step of, after the step of pressing the graphene film against the self-assembled film, removing the support film from the graphene film.

14. A semiconductor device, comprising:
a semiconductor substrate; and
a layered structure on the semiconductor substrate, the layered structure including
a mica layer,
an atomically flat monolayer on the mica layer, and
a graphene layer on the atomically flat monolayer.

15. The semiconductor device of claim 14, wherein the atomically flat monolayer includes a hydrophobic portion.

16. The semiconductor device of claim 14, further comprising an insulating layer between the semiconductor substrate and the layered structure, wherein the mica layer is in contact with the insulating layer.

17. The semiconductor device of claim 16, further comprising:
a drain electrode in contact with the graphene layer and the insulating layer;
a source electrode in contact with the graphene layer and the insulating layer;
a gate insulating film on the graphene layer and between the drain electrode and the source electrode; and
a gate electrode on the gate insulating film.

18. The semiconductor device of claim 16, further comprising:
a drain electrode in contact with the graphene layer and the insulating layer; and
a source electrode in contact with the graphene layer and the insulating layer;
wherein the semiconductor substrate is conductive.
